(19) United States
(12) Patent Application Publication
(10) Pub. No.: US 2024/0186765 A1
(43) Pub. Date: Jun. 6, 2024

(54) METHOD FOR MANUFACTURING A LIGHT EMITTING SEMICONDUCTOR CHIP AND LIGHT EMITTING SEMICONDUCTOR CHIP

(71) Applicant: ams-OSRAM International GmbH, Regensburg (DE)

(72) Inventors: Sven Gerhard, Alteglofsheim (DE); Lars Nähle, Bad Abbach (DE)

(21) Appl. No.: 18/553,434

(22) PCT Filed: Apr. 13, 2022
(86) PCT No.: PCT/EP2022/059893

§ 371 Date: Sep. 29, 2023

(30) Foreign Application Priority Data
Apr. 20, 2021 (DE) 102021109986.2

(51) Int. Cl. H01S 5/10; H01S 5/02; H01S 5/20; H01S 5/323

(52) U.S. Cl. CPC H01S 5/1082; H01S 5/0207; H01S 5/1057; H01S 5/106; H01S 5/2086; H01S 5/32341

(57) ABSTRACT

In an embodiment a method for manufacturing a light-emitting semiconductor chip includes providing a substrate having a main surface with at least one recess, the main surface having a main extension plane along the longitudinal direction and along a transversal direction perpendicular to the longitudinal direction, wherein the substrate has pre-patterning trenches formed along the transversal direction between chip regions and extending along the longitudinal direction, growing the semiconductor layer sequence on the main surface with the at least one recess and forming at least one facet aligned along the transversal direction in the semiconductor layer sequence by an etching process, wherein the facet has a distance of less than or equal to 50 μm from the at least one recess in at least one direction parallel to the main extension plane of the main surface.

### CROSS-REFERENCE TO RELATED APPLICATIONS

This patent application is a national phase filing under section 371 of PCT/EP2022/059893, filed Apr. 13, 2022, which claims the priority of German patent application 102021109986.2, filed Apr. 20, 2021, each of which is incorporated herein by reference in its entirety.

### TECHNICAL FIELD

A method for manufacturing a light-emitting semiconductor chip and a light-emitting semiconductor chip are specified.

### BACKGROUND

For edge-emitting semiconductor components, in particular edge-emitting lasers, for example, it is of particular importance that the light-emitting “edge” of the semiconductor body, i.e. the facet through which light is coupled out of the semiconductor body, is cleanly defined. This means that the facet should be as smooth as possible and perpendicular to the light propagation, at least in the region where the light is coupled out. Typically, the facet is produced by a breaking process in which the semiconductor crystal optimally breaks perfectly parallel to a crystal plane and without dislocations.

However, breaking processes have certain disadvantages. For example, they are at least partly serial and not parallel methods, which are time-consuming and, consequently, costly. Furthermore, depending on the material system, topography and deposited materials, breaking results are often still not optimal in terms of the desired smoothness and perpendicularity. For example, steps can form in the fracture edge. This can negatively influence the laser properties. The method is particularly critical in the GaN material system.

A desired process that would allow parallel processing and thus could be performed quickly and cost-efficiently would be the definition of the facet by an etching process at wafer level. However, for example in the case of GaN semiconductor devices, but also in other material systems, the optically active layers typically have a high In content, which can be up to 20% or even more in the case of green emitting semiconductor devices. It has been found that when etching with typically used solutions containing OH⁻ ions, for example KOH, In-rich layers are often etched faster than layers with smaller or no In content. The higher etch rate of In-rich layers can then also expose crystal planes that lead to an unevenly etched surface profile and/or to under-etching, thus making smooth preparation of a laser facet impossible. At the same time, other areas of an etched facet cannot yet be smooth enough due to an etching time that is too short for these areas, while too much etching has already been performed on the In-richer areas.

### SUMMARY

Embodiments provide a method for manufacturing a light-emitting semiconductor chip. Further embodiments provide a light emitting semiconductor chip.

According to at least one embodiment, in a method for fabricating a light-emitting semiconductor chip, a semiconductor layer sequence is deposited on a substrate.

According to at least one further embodiment, a light emitting semiconductor chip comprises a semiconductor layer sequence having an active region extending along a longitudinal direction, the active region being intended and configured for generating light in operation of the semiconductor chip with a radiation direction along the longitudinal direction.

The embodiments and features described above and below apply equally to the method for fabricating the light-emitting semiconductor chip and to the light-emitting semiconductor chip.

Depending on the desired wavelength to be generated, the light-emitting semiconductor chip can have a semiconductor layer sequence that can be manufactured on the basis of different semiconductor material systems. For long-wave, infrared to red radiation, for example, a semiconductor layer sequence based on InₓGa_{y}Al_{1-x-y}As or on InₓGa_{y}Al_{1-x-y}Sb, for red to yellow radiation, for example, a semiconductor layer sequence based on InₓGa_{y}Al_{1-x-y}P and for short-wave visible, i.e. in particular in the range from green to blue light, and/or for UV radiation, for example a semiconductor layer sequence based on InₓGa_{y}Al_{1-x-y}N is suitable, where in each case 0≤x≤1 and 0≤y≤1.

In particular, the semiconductor layer sequence can be a grown semiconductor layer sequence. For this purpose, the semiconductor layer sequence is grown on the substrate. In particular, the semiconductor layer sequence can be grown on a substrate, which can also be referred to as a growth substrate, by means of an epitaxy process, for example metal-organic vapor phase epitaxy (MOVPE) or molecular beam epitaxy (MBE), and provided with electrical contacts. The substrate is particularly preferably provided as a wafer. By singulating the substrate with the grown semiconductor layer sequence, a plurality of light-emitting semiconductor chips can be fabricated, each singulated semiconductor chip corresponding to a chip region on the substrate before singulation. Furthermore, the semiconductor body can be transferred to a carrier substrate prior to singulation, and the growth substrate can be thinned or removed entirely. For example, the substrate can comprise or be made of a semiconductor material, such as a compound semiconductor material system mentioned above. In particular, the substrate can comprise or be made of sapphire, GaAs, GaP, GaN, InP, SiC, Si, and/or Ge.

The light-emitting semiconductor chip can have an active layer that has, for example, a conventional pn junction, a double heterostructure, a single quantum well structure (SQW structure) or a multiple quantum well structure (MQW structure). Furthermore, cascades of type II transitions (ICL: “interband cascade laser”) or transitions only in the conduction band (QCL: “quantum cascade laser”) are possible.

To define an active region in the active layer, the light-emitting semiconductor chip can have at least one active region defining element, which can be, for example, a ridge waveguide structure and/or a contact region of the semiconductor layer sequence with an electrode layer. Furthermore, for example, current spreading layers and/or current limiting layers can also contribute to a definition of an active region. One or more active regions can be defined in the active layers of the light emitting semiconductor chip. Even though the following description focuses on a light emitting semiconductor chip with exactly one active region, the embodiments and features described below apply equally to light emitting semiconductor chips with multiple active regions.

In addition to the active layer, the light-emitting semiconductor chip can have further functional layers and functional regions, such as p- or n-doped charge carrier transport layers, i.e. electron or hole transport layers, undoped or p- or n-doped confinement, cladding or waveguide layers, barrier layers, planarization layers, buffer layers, protective layers and/or electrical contact layers such as electrode layers, and combinations thereof. It can also be possible for such layers and regions to help define an active region. Furthermore, additional layers, such as buffer layers, barrier layers and/or protective layers, can also be arranged perpendicular to the growth direction of the semiconductor layer sequence, for example around the light emitting semiconductor chip, such as on the side surfaces of the light emitting semiconductor chip.

To fabricate the light emitting semiconductor chip, a substrate is provided which has a main surface forming a growth surface on which the semiconductor layer sequence is grown. The main surface has a main extension plane along the longitudinal direction and along a transversal direction perpendicular to the longitudinal direction. The longitudinal and transversal directions refer to the light-emitting semiconductor chip fabricated in the described method. Directions parallel to the main extension plane of the main surface of the substrate can also be generally referred to as lateral directions. Thus, the longitudinal direction and the transversal direction are two possible lateral directions. The growth direction of the semiconductor layer sequence that is perpendicular to the longitudinal direction and the transversal direction, and thus perpendicular to the main surface of the substrate, is called the vertical direction.

In particular, the light-emitting semiconductor chip can be formed as an edge-emitting laser diode chip in which the at least one active region extends in the longitudinal direction. The active region can be delimited in the longitudinal direction, for example, by facets that can form an optical cavity. The distance between the facets measured in the longitudinal direction, for example between a light outcoupling surface and a back surface, can also be referred to as the cavity length in the following.

Furthermore, the substrate has at least one recess in the main surface extending into the substrate from the main surface. The at least one recess thus has a depth in the vertical direction. The semiconductor layer sequence is grown on the main surface having the at least one recess. In other words, the at least one recess is overgrown with the semiconductor layer sequence and can thereby be at least partially or completely filled with semiconductor material of the semiconductor layer sequence. For example, the at least one recess in the main surface of the substrate can be formed in the main surface using an etching process. As described further below, the substrate can preferably be provided with a plurality of recesses. For this purpose, all the recesses in the main surface of the substrate can preferably be formed simultaneously using suitable masking processes. Simultaneously therewith or also temporally separated therefrom, the pre-patterning trenches described further below can also be formed in the main surface.

Furthermore, at least one facet aligned along the transversal direction is formed in the semiconductor layer sequence. In particular, the facet forms an interface of the semiconductor layer sequence and is formed in such a way, at least in the active region, that light generated in the active region is coupled out of the semiconductor layer sequence through the facet during subsequent operation of the light-emitting semiconductor chip. Particularly preferably, the facet is formed perpendicular to the longitudinal direction, so that the semiconductor layer sequence has at least one facet which is preferably formed perpendicular to the longitudinal direction and thus along the transversal direction and the vertical direction.

The facet can preferably have a small distance from the at least one recess in the main extension plane of the substrate in at least one lateral direction, i.e., a direction parallel to the main extension plane of the main surface. In particular, a distance referred to as a “small distance” in the present description can be a distance of less than or equal to 50 μm or less than or equal to 20 μm or less than or equal to 15 μm or less than or equal to 10 μm or even less than or equal to 5 μm. The “small distance” is measured along a lateral direction, unless otherwise described, and thus denotes a lateral offset from each other. In other words, when looking at the semiconductor layer sequence along the vertical direction, the facet in the semiconductor layer sequence is formed at least partially over and/or offset in a lateral direction at least only slightly, i.e., with a small distance, from the at least one recess in the main surface of the substrate. For example, the facet can thus be formed at least partially above the recess in the vertical direction aligned perpendicular to the main extension plane. A facet having a small distance in the lateral direction from a recess in the main surface of the substrate is also referred to herein and hereinafter as “associated with the recess”. Similarly, a recess in the main surface of the substrate that has a small distance in the lateral direction from a facet is also referred to herein and hereinafter as “associated with the facet”. For example, the at least one recess can have a small distance along the longitudinal direction and/or along the transversal direction from the facet.

Particularly preferably, a plurality of light-emitting semiconductor chips is produced in the method for producing the light-emitting semiconductor chip. For this purpose, the semiconductor layer sequence grown on the substrate can have a plurality of chip regions, each chip region corresponding to a subsequent light-emitting semiconductor chip, wherein the process steps described above and below apply to each chip region. In other words, the semiconductor layer sequence forms a composite of a plurality of chip regions. A plurality of recesses can be provided in the main surface of the substrate, wherein each chip region is associated with at least one recess in the main surface, a facet aligned along the transversal direction is formed in the semiconductor layer sequence in each chip region, and for each chip region, the facet is spaced a small distance from the at least one associated recess in at least one lateral direction. By singulating the semiconductor layer sequence corresponding to the chip regions, a plurality of light-emitting semiconductor chips can be fabricated. Accordingly, a plurality of light emitting semiconductor chips can be fabricated, wherein a plurality of facets are fabricated and each of the facets has a distance of less than or equal to 20 μm or other small distance from at least one recess in the main surface of the substrate in at least one direction parallel to the main extension plane. Here, each chip region can be associated with at least one recess of its own. Furthermore, it can also be possible for a recess to be associated with several chip regions, for example at least two or more adjacent chip regions.

The following description refers for the most part by way of example to a chip region corresponding to a later light-emitting semiconductor chip. However, the described embodiments and features can preferably apply equally to all chip regions, so that a plurality of similar light-emitting semiconductor chips can be produced.

The at least one facet is particularly preferably produced by means of an etching process. This can involve dry etching, in particular plasma etching, or wet etching, i.e. etching with a chemical solution, or a combination of wet and dry etching. A combination of wet and dry etching can be particularly advantageous, wherein a wet chemical etching step in particular can promote the best possible smoothness of the facet.

Particularly preferably, a trench with a main extension direction in the transversal direction can be formed in the semiconductor layer sequence for producing the at least one facet. The at least one facet is formed in particular by a side wall of the trench. The trench is produced, as described above, in particular by an etching process. The trench can be limited in its expansion to the associated chip region, so that for each chip region at least one trench is formed which is spaced from the trenches of the other chip regions. However, it is also possible for a trench to be associated with at least two or more chip regions, so that a facet can be formed in each case by forming the trench in at least two or more chip regions. The formation of multiple trenches is preferably done in a parallel process step, for example by using suitable mask processes to define all trenches to be formed in the semiconductor layer sequence.

For example, the substrate with the semiconductor layer sequence along the trench can be broken or etched for singulation of the light emitting semiconductor chip, i.e., to separate the compound of chip regions into individual light emitting semiconductor chips. In this case, the trench can form at least part of a singulation structure that can facilitate singulation by breaking or by another etching process in addition to the etching process to produce the at least one facet. In this case, the facet can preferably be a light outcoupling surface of the semiconductor layer sequence of the light emitting semiconductor chip through which light can be emitted into the environment during operation of the light emitting semiconductor chip. The light outcoupling surface can, for example, be provided with a coating such as an anti-reflective coating or a partially reflective coating after the facet has been manufactured. Alternatively or additionally, a back surface of the semiconductor layer sequence of the light emitting semiconductor chip formed by a facet can be fabricated by the method described. For example, a coating such as a coating that is as highly reflective as possible or a partially reflective coating can be applied to the back surface after the facet has been fabricated. Particularly preferably, two facets can be formed by means of a trench for two chip regions adjacent in the longitudinal direction, one of the trenches forming a light outcoupling surface for one of the two chip regions, while the opposite facet forms a back surface for the other of the two chip regions.

Furthermore, by means of the method described, a transversely extending trench can also be formed, which is arranged in the light-emitting semiconductor chip in the longitudinal direction between a light outcoupling surface and a rear surface, so that the trench and thus two facets lying opposite each other, with respect to the longitudinal direction, are located within the light-emitting semiconductor chip. Such a trench can allow, for example, wavelength adjustment and/or subdivision into a plurality of functional regions of the light emitting semiconductor chip. The facets can be uncoated in the light emitting semiconductor chip. Furthermore, one of the two facets or both facets can be provided with a coating, for example an anti-reflective coating, a partially reflective coating, or a coating that is as highly reflective as possible. In particular, the two facets can also be provided with different coatings.

If a plurality of facets for the light emitting semiconductor chip are fabricated by the method described, at least one recess can be associated with each of the facets to be fabricated in the semiconductor layer sequence in the main surface of the substrate. Furthermore, at least one first facet and at least one second facet can be formed in the semiconductor layer sequence, each of the first and second facets being associated with at least one same recess. Furthermore, particularly in the case of a recess arranged, with respect to the longitudinal direction, between a light outcoupling surface and a back surface of the light emitting semiconductor chip, at least one recess in the main surface can be associated with both facets formed by the recess.

Furthermore, the substrate can have, for example, at least two recesses in the main surface, wherein the facet is formed symmetrically to the at least two recesses. This can mean that there is a plane of symmetry with respect to the two recesses, which is also a plane of symmetry for the facet. Accordingly, an active region defining element can also be formed symmetrically with respect to the at least two recesses.

The at least one recess can particularly preferably have a depth of greater than or equal to 0.5 μm or greater than or equal to 1 μm or greater than or equal to 2 μm or greater than or equal to 5 μm and less than or equal to 15 μm. Furthermore, the at least one recess can have an expansion in the longitudinal direction that is less than or equal to 30% and preferably less than or equal to 20% of the cavity length. For example, the at least one recess can have an expansion in the longitudinal direction that is less than or equal to 100 μm or less than or equal to 50 μm. In other words, the at least one recess can be limited, particularly in the longitudinal direction, and may not extend along the longitudinal direction over the entire main surface of the substrate. In this regard, the at least one recess can, for example, have a main direction of extension in the longitudinal direction. Alternatively, the at least one recess can have a main extension direction in the transversal direction. For example, the at least one recess can have a rectangular or circular cross-section in the main extension plane of the main surface of the substrate.

Furthermore, it can be possible for the substrate to have pre-patterning trenches formed between the chip regions, as viewed in the transversal direction, and extending along the longitudinal direction. Such pre-patterning trenches, preferably extending substantially completely and continuously across the substrate in the longitudinal direction, can divide the main surface of the substrate into non-contiguous “strips”. This allows the actual contiguous growth area to be divided into smaller growth areas, thereby reducing strains in the semiconductor layer sequence.

Purely by way of example, the effects of pre-patterning trenches and the at least one recess on the influence of the In content during the growth of a nitride compound semiconductor material system, i.e. in a GaN-based material system, are described below. Corresponding effects can also be associated with the content of one or more other components of a nitride compound semiconductor material system or other compound semiconductor material system, for example in GaAs-, InP- and GaSb-based material systems.

When growing semiconductor layers with high In content in the nitride compound semiconductor material system, such as those required for green emitting semiconductor chips, strains can occur. For example, in GaN-based semiconductor chips emitting in the blue and especially in the green wavelength range, the active region, for example quantum well structures with InGaN layers, can have a very high In content of up to about 20 atomic %. In contrast, near an epitaxial overgrown pre-patterning trench, the growth of the semiconductor layer sequence can be impaired. In particular, for example, the In content can be lowered so that strains in the semiconductor layer sequence can be reduced. The purpose of the pre-patterning trenches can thus be to reduce defects, i.e. to achieve growth that is as defect-free as possible, even of layers with a high In content, and thus to achieve good function, especially in the active region. To achieve the most undisturbed growth of an active region possible, the pre-patterning trenches, measured along the transversal direction, are introduced at a large distance of several 10 μm from the active region or from an active region defining element, such as a ridge waveguide structure in the substrate. As a result, the pre-patterning trenches particularly preferably have no influence on the composition of the semiconductor layers in the active regions.

In the method described herein for manufacturing a light-emitting semiconductor chip, in addition or as an alternative to such pre-patterning trenches, the at least one recess in the main surface, on the other hand, is arranged very close, i.e. at a small distance defined above, to the facet to be manufactured, at least in some regions. Accordingly, the at least one recess is arranged very close to the active region or an active region defining element, for example a ridge waveguide structure and/or a contact region of the semiconductor layer sequence with an electrode layer. Advantageously, the effect of the at least one recess is used that in the vicinity of the epitaxially overgrown recess the growth of the semiconductor layer sequence is disturbed and, for example, the In content can be reduced. The position and expansion of the at least one recess are selected in such a way that the growth disturbance is essentially present in the region of the facet to be produced, so that the In content can be reduced in the region of the facet to be produced in the example described here.

As described above, the etch rate of semiconductor layers with high In content can be significantly higher than that of semiconductor layers with low In content or In-free semiconductor layers. Due to the growth disturbance caused by the at least one recess, the In content in a semiconductor layer with actually high In content can be locally lowered in such a way that a more uniform etching is possible and an unevenly etched surface profile and/or under-etching at the facet can be prevented or at least reduced. There is no need to worry about a loss of performance or a lowered wavelength with respect to the light generated in the active region during operation, since the majority of the semiconductor chip, which can typically have a length in the longitudinal direction of more than 300 μm and often even more than 900 μm or even more than 1200 μm, runs in the region of undisturbed epitaxy. For example, this length can be the cavity length. Furthermore, it can be possible that by forming the facet, i.e. in particular by etching the trench as described above to form the facet, at least part of the epitaxial region with lowered In content is removed.

The wet chemical facet etching can thus be homogenized due to the sectionally reduced In content in the semiconductor layer sequence caused by the at least one recess. The achievement of very smooth and perpendicular facets can thus be made possible by the at least one recess in the main surface of the substrate. By the at least one recess in the main surface of the substrate in the vicinity of the facet to be formed, the process window, i.e. for example the etching time and/or the etching rate, for example depending on the temperature and the concentration of the etchants, can be enlarged with advantage, since the disadvantageous effect of a layer with a large In content can be reduced or even eliminated, which can lead to improved finishability in the form of improved facet smoothing.

According to a further embodiment, at least one semiconductor layer of the semiconductor layer sequence in the region of the facet exhibits a variation of one or more parameters selected from layer thickness, material composition and orientation of a crystal axis. “In the region of the facet” can in particular mean a distance from the facet along a lateral direction such as the longitudinal direction of less than or equal to 50 μm. In particular, “in the region of the facet” can mean a small distance from the facet as defined above. In particular, the variation of the parameter or parameters can be caused by the described disturbance induced in the semiconductor layer sequence by the at least one recess in the main surface of the substrate. For example, the at least one semiconductor layer having the parameter variation can be the active layer, a waveguide layer, or a cladding layer. Furthermore, the at least one semiconductor layer with the parameter variation can also be a plurality of semiconductor layers or even all semiconductor layers of the semiconductor layer sequence.

For example, the at least one semiconductor layer, such as the active layer, can have a thickness in the facet region that decreases as the distance to the facet decreases in the longitudinal direction. Furthermore, the semiconductor layer sequence can have a thickness in the region of the facet that decreases as the distance to the facet decreases in the longitudinal direction. Following the longitudinal direction, the at least one semiconductor layer and/or the semiconductor layer sequence can thus become thinner as it approaches the facet. Alternatively or additionally, the at least one semiconductor layer, such as the active layer, can have a material composition wherein a relative proportion, for example measured in atomic %, of a component of the material composition in the region of the facet decreases with decreasing distance from the facet in the longitudinal direction. In other words, following the longitudinal direction, the at least one semiconductor layer can thus have a reducing relative proportion of a constituent of the material composition as it approaches the facet.

Furthermore, the at least one semiconductor layer, for example the active layer, can have a thickness at the facet, measured in the vertical direction, that decreases along the transversal direction. Furthermore, the semiconductor layer sequence at the facet can have a thickness that decreases along the transversal direction. Thus, the thickness of the at least one semiconductor layer and/or the semiconductor layer sequence can vary at the facet depending on the transverse position. Alternatively or additionally, the at least one semiconductor layer, such as the active layer, can have a material composition wherein a relative proportion of a component of the material composition at the facet decreases in a transversal direction.

Furthermore, the semiconductor layer sequence can have a crystal axis tilt in the region of the facet, which increases with decreasing distance to the facet along the longitudinal direction. In particular, this can mean that the substrate has a first crystal axis at the main surface. The semiconductor layer sequence can have a second crystal axis, for example in the active layer or on a side facing away from the substrate. Far from any recesses in the substrate, i.e., in a region of the substrate having a large distance, for example, a distance greater than or equal to 100 μm, from any recesses in the main surface of the substrate, the second crystal axis can be substantially parallel to the first crystal axis, for example. It can also be possible for the first and second crystal axes to include some angle in such a region remote from recesses in the main surface of the substrate, but for this angle to remain substantially the same over the remote region. In the facet region, however, the angle between the first and second crystal axes can increase as the distance from the facet decreases along the longitudinal direction.

Further advantages, advantageous embodiments and further developments are revealed by the embodiments described below in connection with the figures.

### BRIEF DESCRIPTION OF THE DRAWINGS

FIGS. 1A and 1B show schematic illustrations of a light-emitting semiconductor chip according to an embodiment;

FIG. 2 shows a schematic illustration of a light-emitting semiconductor chip according to a further embodiment;

FIGS. 3A to 3F show schematic illustrations of method steps of a method for manufacturing a light-emitting semiconductor chip according to further embodiments;

FIG. 4 shows a schematic illustration of a method step of a method for manufacturing a light-emitting semiconductor chip according to a further embodiment;

FIGS. 5A and 5B show layer characteristics of at least one semiconductor layer of a light-emitting semiconductor component according to further embodiments; and

FIGS. 6A to 6N show schematic illustrations of method steps of a method for manufacturing a light-emitting semiconductor chip according to further embodiments.

### DETAILED DESCRIPTION OF ILLUSTRATIVE EMBODIMENTS

In the embodiments and figures, identical, similar or identically acting elements are provided in each case with the same reference numerals. The elements illustrated and their size ratios to one another should not be regarded as being to scale, but rather individual elements, such as for example layers, components, devices and regions, may have been made exaggeratedly large to illustrate them better and/or to aid comprehension.

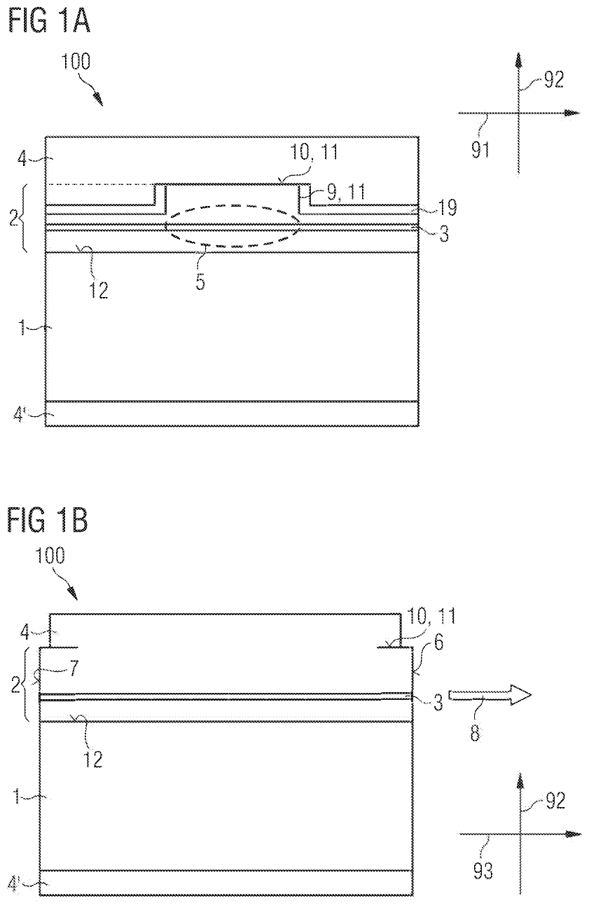

FIGS. 1A and 1B show an embodiment of a light-emitting semiconductor chip 100 that can be manufactured within the scope of the process steps described below, wherein FIG. 1A shows a top view of a facet 6 of the light-emitting semiconductor chip 100 formed as a light extraction surface and FIG. 1B shows a representation of a section through the light-emitting semiconductor chip 100 with a section plane perpendicular to the facet 6. In particular, the light-emitting semiconductor chip 100 is formed as an edge-emitting semiconductor laser diode according to the embodiment shown.

As shown in FIGS. 1A and 1B, a substrate 1 is provided, which in the shown embodiment is a growth substrate for a semiconductor layer sequence 2 fabricated thereon by an epitaxial process and which has a main surface 12 that forms the growth surface for the semiconductor layer sequence 2.

Alternatively, the substrate 1 can be, for example, a carrier substrate onto which a semiconductor layer sequence 2 grown on a growth substrate is transferred after growth. For example, the substrate 1 can be GaN on which a semiconductor layer sequence 2 based on an InAlGaN compound semiconductor material is grown. Furthermore, other materials, in particular as described in the general part, are also possible for the substrate 1 and the semiconductor layer sequence 2. Alternatively, it is also possible that the completed light emitting semiconductor chip 100 is free of a substrate. In this case, the semiconductor layer sequence 2 can be grown on a growth substrate which is subsequently removed.

The semiconductor layer sequence 2 has an active layer 3 with an active region 5, which is suitable for generating light 8, in particular laser light when the laser threshold is exceeded, during operation of the light-emitting semiconductor chip and for radiating it into the environment via the facet 6.

As indicated in FIGS. 1A and 1B, here and in the following, the transversal direction 91 is referred to as a direction parallel to a main extension direction of the layers of the semiconductor layer sequence 2 when viewed from above the facet 6. The arrangement direction of the layers of the semiconductor layer sequence 2 on each other and of the semiconductor layer sequence 2 on the substrate 1 is referred to herein and hereinafter as the vertical direction 92. The direction perpendicular to the lateral direction 91 and the vertical direction 92, which corresponds to the radiation direction, i.e. the direction along which the light 8 is radiated during operation of the light-emitting semiconductor chip 100, is referred to herein and hereinafter as the longitudinal direction 93. Directions parallel to the plane spanned by the transversal direction 91 and the longitudinal direction 93, which corresponds to the main extension plane of the main surface 12 of the substrate 1, can also be referred to as lateral directions.

In the top side of the semiconductor layer sequence 2 facing away from the substrate 1, a ridge waveguide structure 9 is formed according to an embodiment by removing part of the semiconductor material from the side of the semiconductor layer sequence 2 facing away from the substrate 1. For this purpose, a suitable mask can be applied to the grown semiconductor layer sequence 2 in the region where the ridge is to be formed. Semiconductor material can be removed by an etching process. Subsequently, the mask can be removed again. The ridge waveguide structure 9 is formed by such a method in such a way that a ridge extends in the longitudinal direction 93 and is delimited in the lateral direction 91 on both sides by side surfaces, which can also be referred to as ridge side surfaces or ridge sides.

The semiconductor layer sequence 2 can have further semiconductor layers in addition to the active layer 3, such as buffer layers, cladding layers, waveguide layers, barrier layers, current spreading layers and/or current limiting layers. For example, the semiconductor layer sequence 2 on the substrate 1 can have, for example, a buffer layer, above it a first cladding layer and above it a first waveguide layer, on which the active layer 3 is deposited. A second waveguide layer, a second cladding layer, and a semiconductor contact layer can be deposited over the active layer 3.

If the semiconductor layer sequence 2 is based on an InAlGaN compound semiconductor material as described above, the buffer layer can comprise or be undoped or n-doped GaN, the first cladding layer n-doped AlGaN, the first waveguide layer n-doped GaN, the second waveguide layer p-doped GaN, the second cladding layer p-doped AlGaN, and the semiconductor contact layer p-doped GaN. For example, Si can be used as the n-dopant, and Mg can be used as the p-dopant. The active layer 3 can be formed by a pn junction or by a quantum well structure with a plurality of layers formed, for example, by alternating layers with or of InGaN and GaN. Depending on the wavelengths to be generated, the In content can be up to 20 atomic % in the InGaN layers. For example, the substrate 1 can have or be n-doped GaN. Alternatively, other layer and material combinations as described above in the general part are also possible.

For example, in a structure of the semiconductor layer sequence 2 as described above, the ridge waveguide structure 9 can be formed by the semiconductor contact layer and a part of the second cladding layer. Due to the refractive index jump at the side surfaces of the ridge waveguide structure 9 to an adjacent material as well as in case of a sufficient proximity to the active layer 3, a so-called index guiding of the light generated in the active layer 3 can be effected, which can decisively lead to the formation of the active region 5, which indicates the region in the semiconductor layer sequence 2 in which, during laser operation, the generated light is guided and amplified in the form of one or more laser modes. The ridge waveguide structure 9 thus forms an element 11 defining the active region. It can also be possible for the ridge waveguide structure 9 to have a height less than or greater than the height shown, i.e., less or more semiconductor material can be removed to form the ridge waveguide structure 9. For example, the ridge waveguide structure 9 can be formed by only a semiconductor contact layer or a part thereof, or by the semiconductor contact layer and the second cladding layer. By adjusting the height of the ridge waveguide structure 9, an adjustment of the index guiding can be achieved. As the height and/or the distance of the ridge waveguide structure 9 to the active layer 3 becomes smaller, the expression of the index guide can be reduced. The mode guiding in the active region 5 then takes place at least in part by a so-called gain guiding.

For electrical contacting, electrical contact layers 4, 4′ are applied to the top side facing away from the substrate 1 and to the bottom side of the substrate 1 facing away from the semiconductor layer sequence 2, which can have one or more metals and/or metal alloys in one or more layers. For example, a dielectric layer 19 on the ridge side surfaces and the upper side of the semiconductor layer sequence 2 adjacent to the ridge waveguide structure 9 can define a contact area 10 on the ridge waveguide structure 9 through which current can be injected into the semiconductor layer sequence 2 through the contact layer 4 during operation. The size, geometry and nature of the contact area 10 can also have an influence on the formation of the active region 5, so that the contact area 10 can also be an element 11 defining the active region.

Furthermore, reflecting or partially reflecting layers or layer sequence, which are not shown in the figures for the sake of clarity and which are intended and configured for forming an optical resonator in the semiconductor layer sequence 2, can be applied to the facet 6 forming the light outcoupling surface and the opposite facet 7 forming a back surface, which form side surfaces of the semiconductor layer sequence 2 and of the substrate 1. The distance between the facets 6, 7 along the longitudinal direction 93 can also be referred to as the cavity length.

As shown in FIG. 1A, the ridge waveguide structure 9 can be formed by completely removing semiconductor material transversely on both sides adjacent to the ridge 9. Alternatively, a so-called “tripod” can be formed in which semiconductor material is removed transversely adjacent to the ridge waveguide structure 9 along only two grooves to form the ridge waveguide structure 9. Alternatively, the light emitting semiconductor chip 100 can be formed as a so-called wide stripe laser diode in which the semiconductor layer sequence 2 is formed without a ridge waveguide structure or with a ridge waveguide structure having a small height.

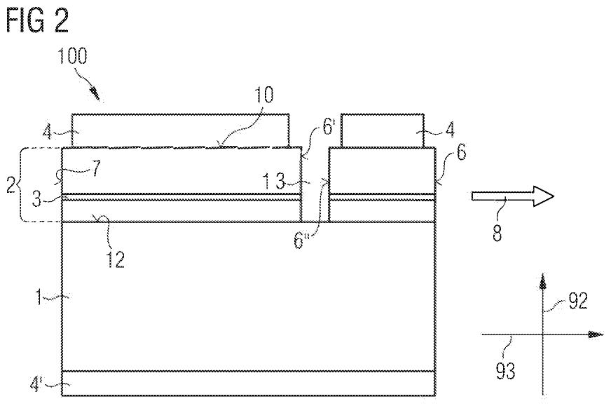

FIG. 2 shows another embodiment of a light emitting semiconductor chip 100 which, compared to the previous embodiment, has a trench 13 which has a main extension direction in the transversal direction and which, viewed along the longitudinal direction 93, is arranged between the facet 6 formed as a light outcoupling surface and the facet 7 formed as a back surface, so that the trench 13 and thus two opposing facets 6′, 6″ formed by the side walls of the trench 13 are located within the light emitting semiconductor chip 100. Such a trench can also be referred to as an internal trench. Such a trench 13, which can extend purely by way of example in the vertical direction 91 through the entire semiconductor layer sequence 2 to the main surface 12 of the substrate 1 or alternatively can have a lesser depth, can enable, for example, wavelength adjustment and/or subdivision of the light emitting semiconductor chip 100 into a plurality of functional regions. The facets 6′, 6″ of the trench 13 can be uncoated in the light emitting semiconductor chip 100. Furthermore, one of the two facets 6′, 6″ or both facets 6′, 6″ can be provided with a coating, for example an anti-reflective coating, a partially reflective coating or a coating that is as highly reflective as possible. Furthermore, the two facets 6′, 6″ can also be provided with different coatings.

The trench 13 can divide the light emitting semiconductor chip 100 into regions having different functionalities. For example, the region between the facet 7 forming the back surface and the nearest facet 6′ of the trench 13 can form the laser resonator, so that in this case the distance between facets 6′, 7 along the longitudinal direction 93 can be referred to as the cavity length. A region separated from the laser resonator by a trench can form, for example, a photodiode or an optical modulator.

In connection with the following figures, method steps of a method for manufacturing a light emitting semiconductor chip 100 according to a plurality of embodiments are described, wherein the light emitting semiconductor chip 100 can, for example, be embodied according to one of the previous embodiments. To this end, the substrate 1 can have one or more recesses in the main surface 12 as described below, which are not shown in FIGS. 1A to 2.

In particular, the following description concentrates on the fabrication of one or more facets in the semiconductor layer sequence 2, i.e., for example, one or more of the facets 6, 6′, 6″, 7 described above. Purely exemplary process steps are shown in connection with the following figures, which serve to fabricate the facets 6, 7 formed as light outcoupling surface and rear surface. The production of facets 6′, 6″ formed by side walls of an internal trench 13 can be carried out analogously. Particularly preferably, the facets are formed perpendicular to the longitudinal direction 93 in the process steps described below, so that the semiconductor layer sequence 2 has at least one facet which is preferably formed perpendicular to the longitudinal direction 93 and thus along the transversal direction 92 and the vertical direction 91.

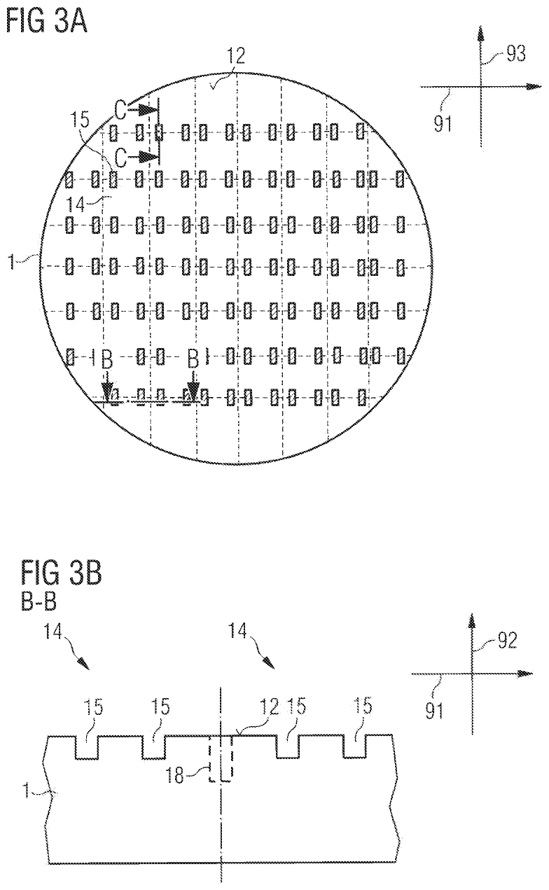

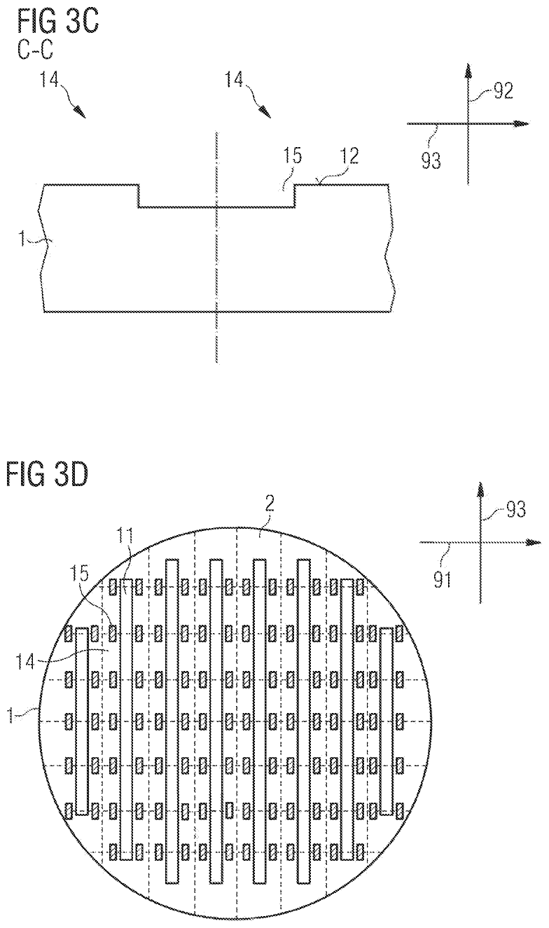

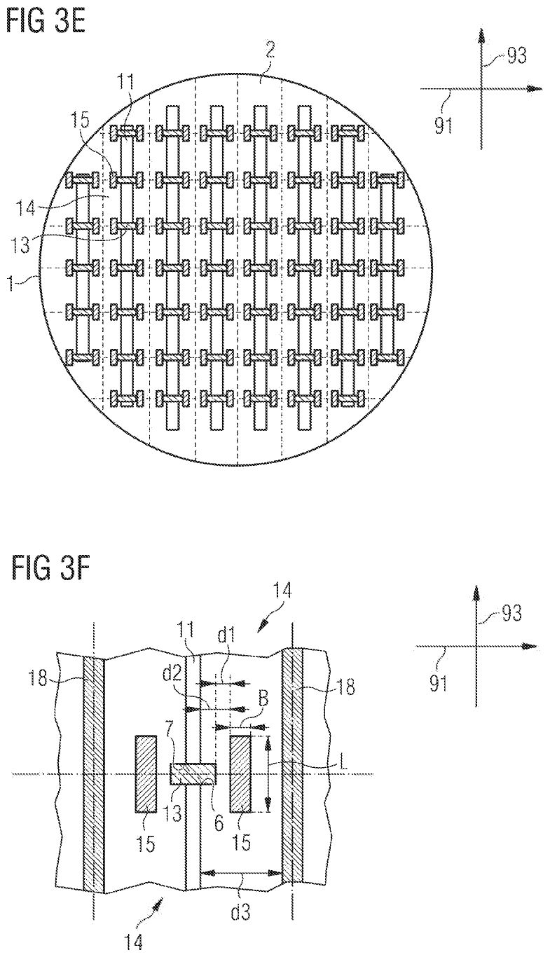

FIGS. 3A to 3C show a first method step of a method for manufacturing a light-emitting semiconductor chip. In particular, FIG. 3A shows a top view of a substrate 1, i.e. in particular of the main surface 12 which forms the growth surface of the substrate 1 for growing the semiconductor layer sequence. FIGS. 3B and 3C show sectional views through the substrate 1 along the sectional planes BB and CC indicated in FIG. 3A.

For the process steps described below, in particular a substrate 1 is provided which has at least one recess 15 in the main surface 12 which extends from the main surface 12 into the substrate 1. The at least one recess 15 thus has a depth measured along the vertical direction. On the main surface 12 with the at least one recess 15, the semiconductor layer sequence is grown in a further process step. Accordingly, the at least one recess 15 can be overgrown with semiconductor material of the semiconductor layer sequence. Thereby, the at least one recess 15 can be at least partially or completely filled with semiconductor material of the semiconductor layer sequence. The at least one recess 15 in the main surface 12 of the substrate 1 can, for example, be introduced into the main surface 12 by means of an etching process.

At least one facet is formed in the grown semiconductor layer sequence, as described below, wherein the at least one facet has a small distance from the at least one recess 15 in the main surface 12 of the substrate 1 in at least one lateral direction, i.e., a direction parallel to the main extension plane of the main surface 12. For example, the at least one recess 15 can have a small distance from the at least one facet to be fabricated in the longitudinal direction 93 and/or in the transversal direction 91. As stated in the general part, a distance is referred to as a “small distance” that is less than or equal to 50 μm or less than or equal to 20 μm or less than or equal to 15 μm or less than or equal to 10 μm or even less than or equal to 5 μm.

As will also become clear in connection with the following description, when the semiconductor layer sequence is viewed along the vertical direction, the at least one facet in the semiconductor layer sequence is formed at least partially above and/or offset in a lateral direction at least only slightly, i.e., at a small distance, from the at least one recess 15. For example, the facet can thus be formed at least partially above the recess 15 when looking at the main surface 12 with a viewing direction along the vertical direction 92 aligned perpendicular to the main extension plane. A facet and a recess to which the facet has a small distance in the lateral direction are referred to as being associated with each other, as described in the general part.

Based on FIGS. 3A to 3C, process steps for manufacturing a plurality of light-emitting semiconductor chips are shown in particular. Accordingly, a substrate 1 is provided which has a plurality of chip regions 14. In FIGS. 3A to 3C, the chip regions 14 are indicated by dashed lines, and each of the chip regions 14, only one of which is indicated by a reference sign in FIG. 3A for clarity, can correspond to a subsequently completed light-emitting semiconductor chip. In particular, at a suitable time after the semiconductor layer sequence has been grown on the substrate 1, a singulation of the substrate with the semiconductor layer sequence into a plurality of individual light-emitting semiconductor chips can be performed.

Furthermore, a plurality of recesses 15 is provided in the main surface 12 of the substrate 1, of which only one is also marked with a reference numeral in FIG. 3A for the sake of clarity. Each chip region 14 is associated with at least one recess 15 in the main surface 12. In the embodiment shown, four recesses 15 are associated with each chip region 14 purely as an example. As can be seen in FIGS. 3A and 3C, it is also possible for a recess 15 to be associated with multiple chip regions 14, for example at least two adjacent chip regions 14.

In particular, at least one facet aligned along the transversal direction 91 is formed in the semiconductor layer sequence in each chip region 14 and, for each chip region, the at least one facet is spaced a small distance from at least one associated recess 15 in at least one lateral direction. Accordingly, starting from the substrate 1 indicated in FIG. 3A in the form of a wafer, a plurality of light emitting semiconductor chips can be fabricated, wherein a plurality of facets are fabricated and each of the facets is spaced a small distance from at least one recess 15 in the main surface 12 of the substrate 1 in at least one direction parallel to the main extension plane.

Furthermore, as indicated in FIG. 3B, a pre-patterning trench 18 can be present in the main surface 12 of the substrate 1 between each two adjacent chip regions 14, preferably extending completely in the longitudinal direction 93 across the main surface 12, which, as described in the general part, can serve to divide the main surface 12 into separate strips in order to reduce stresses and thereby the risk of defect formation in the semiconductor layer sequence.

In a further process step, the semiconductor layer sequence is grown, in particular across large areas and coherently, on the main surface 12 of the substrate 1. Here, in particular, as indicated in FIG. 3D, one or more elements 11 defining the active region, for example ridge waveguide structures and/or suitably structured contact regions, can be provided to define the active region of the subsequently completed light-emitting semiconductor chips. For the sake of clarity, the semiconductor layer sequence is indicated transparently in FIG. 3D so as not to obscure the underlying main surface and in particular the recesses 15 in the main surface in the representation shown. Furthermore, for the sake of clarity, only one element 11 defining the active region is provided with a reference sign.

In a further process step, facets are produced in each chip region which are spaced a short distance along a lateral direction from at least one recess 15 in the main surface 12 of the substrate. As indicated in FIG. 3E and in a detail in FIG. 3F, trenches 13 with a main extension direction in transversal direction 91 are formed for this purpose. For the sake of clarity, again only one trench 13 is marked with a reference sign in FIG. 3E. In FIG. 3F, pre-patterning trenches 18 are also indicated. Furthermore, in FIG. 3F and the other figures, only the elements 11 defining the active region and the trenches 13 with the facets are indicated from the semiconductor layer sequence in order to be able to make their position and configuration clear in relation to the recesses 15 and pre-patterning trenches 18 in the main surface of the substrate, which are also indicated.

Each of the trenches 13 can be limited in its expansion to the associated chip region 14, so that for each chip region 14 at least one trench 13 is formed in the semiconductor layer sequence, spaced from the trenches 13 of the other chip regions 14. However, it is also possible that, as indicated in FIGS. 3E and 3F, a trench 13 is associated with at least two chip regions 14, so that a facet 6, 7 can be formed by forming a trench 13 in each of two adjacent chip regions 14, as can be seen in FIG. 3F. Along the dashed horizontal line indicated in FIG. 3F as the boundary between two chip regions 14, singulation can take place so that one side wall of the trench 13 can form the facet 6 of a light-emitting semiconductor chip formed as a light outcoupling surface and the other side wall of the trench 13 can form the facet 7 of a further light-emitting semiconductor chip formed as a rear surface.

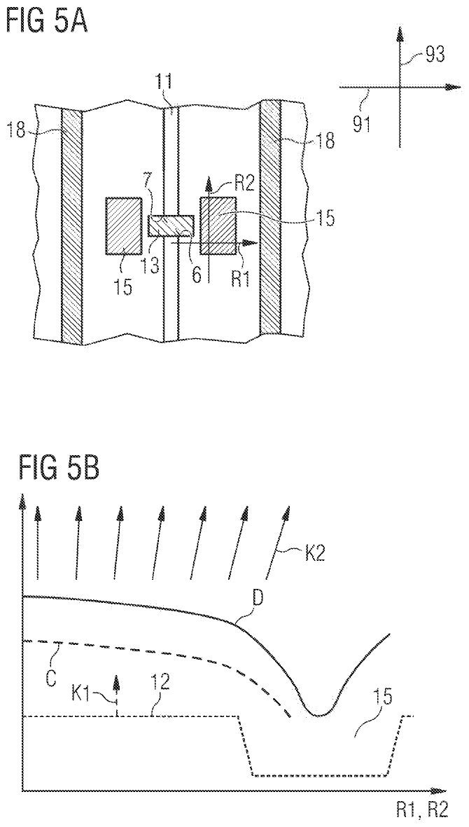

The trenches 13 and thus the facets 6, 7 are particularly preferably produced by means of an etching process. This can be dry etching, in particular plasma etching, or wet etching, i.e. etching with a chemical solution, or a combination of wet and dry etching. A combination of wet and dry etching can be particularly advantageous. In particular, the wet chemical etching step in combination with the influencing of the material composition of, for example, the active layer by the closely spaced recesses 15 in the main surface of the substrate, as described further below in connection with FIGS. 5A and 5B, can promote the smoothest possible facets. Accordingly, the trenches 13 for facet definition can be formed first by dry etching and then by wet chemical etching to define smooth facets 6, 7.

In the shown embodiment, the trenches 13 and thus the facets 6, 7 are formed symmetrically to two recesses 15 each. As indicated in FIG. 3F, the trenches 13 have a distance d1 from an associated recess 15 in the lateral direction, which corresponds to the transversal direction 91 in the shown embodiment, which is a small distance and can be correspondingly less than or equal to 20 μm or less than or equal to 15 μm or less than or equal to 10 μm or even less than or equal to 5 μm. Furthermore, the indicated elements 11 defining the active region have a distance d2 in the lateral direction, which in turn corresponds to the transversal direction 91 in the shown embodiment, which can preferably also be a small distance. The pre-patterning trenches 18, on the other hand, preferably have a distance d3 in the lateral direction from the elements 11 defining the active region, which is so large that the growth of the semiconductor layers in the active region is not influenced by the pre-patterning trenches 18. The distance d3 can preferably be several 10 μm and, for example, be greater than or equal to 50 μm.

The recesses 15 can particularly preferably have a depth of greater than or equal to 0.5 μm or greater than or equal to 1 μm or greater than or equal to 2 μm or greater than or equal to 5 μm and less than or equal to 15 μm. Furthermore, the recesses 15 can have an expansion in the longitudinal direction 93 that is less than or equal to 30% and preferably less than or equal to 20% of the cavity length. For example, the recesses 15 can have an expansion in the longitudinal direction 93 that is less than or equal to 100 μm or less than or equal to 50 μm.

As indicated in FIGS. 3D to 3F, the recesses 15 can have a main direction of extension in the longitudinal direction 93 and thus a length L which can be as described above and which is greater than a width B in the transversal direction 91. For example, the width B can be greater than or equal to 0.5 μm and less than or equal to 15 μm. Alternatively, the recesses 15 can have a main direction of extension in the transversal direction 91, as described further below.

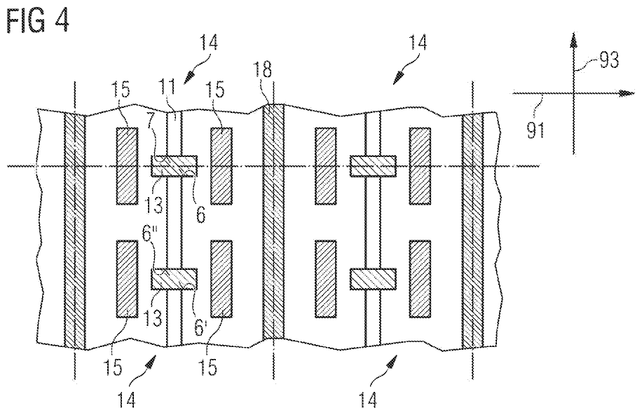

As indicated in FIG. 4, there can also be several trenches 13 in a chip region 14, by means of which, for example, facets 6, 7 for forming the light outcoupling surface and the rear surface as well as further facets 6′, 6″ of an internal trench can be formed within the light-emitting semiconductor chip, as described, for example, in connection with FIG. 2. For this purpose, to the respective trenches 13 and thus the respective facets 6, 6′, 6″, 7 can each be associated recesses 15 at a small distance. The trenches 13 and the associated recesses 15 can be of identical or different design as shown.

As described above in the general part, the recesses 15 have an influence on one or more parameters of the semiconductor layer sequence, as also shown in connection with FIGS. 5A and 5B. In FIG. 5A a trench 13 with two associated recesses 15 is schematically indicated. In FIG. 5B the dependence of different parameters of the semiconductor layer sequence on a lateral distance from a recess 15 is qualitatively indicated, wherein in FIG. 5A purely exemplarily two directions R1, R2 are indicated for the lateral distance. The dashed line indicates a height profile of the main surface 12 of the substrate and thus a position of a recess 15. The recess 15 can have chamfered sidewalls, as indicated in FIG. 5B. Alternatively, vertical or substantially vertical sidewalls are also possible, as indicated for example in FIGS. 3B and 3C.

The effects on several parameters of the semiconductor layer sequence indicated in FIG. 5B can be present in particular in the region of the facets 6, 7 indicated in FIG. 5A, i.e. in particular in each case at a distance from the facets along a lateral direction such as the longitudinal direction 93 of less than or equal to 50 μm or in particular at a small distance. The effects described in the following can be present for at least one semiconductor layer of the semiconductor layer sequence, in particular for example the active layer, or also for the entire semiconductor layer sequence.

As indicated by curve D, at least one semiconductor layer, e.g. the active region, or the entire semiconductor layer sequence in the region of a facet can have a thickness which decreases in the longitudinal direction 93, i.e. parallel to the direction R2 indicated in FIG. 5A, with decreasing distance to the facet. Alternatively or additionally, as indicated by the curve C, at least one semiconductor layer, i.e., for example, the active region, or even the entire semiconductor layer sequence can have a material composition in which a relative proportion of a component of the material composition in the region of a facet decreases in the longitudinal direction 93, i.e., parallel to the direction R2 indicated in FIG. 5A, with decreasing distance from the facet. In an AlInGaN-based semiconductor material system, this can be, for example, the In content and/or the Al content. In particular, a reduction of the In content can cause the improvement of etched facets described in the general part. The described effects can accordingly also be present at a facet in a transversal direction 91, i.e. parallel to the direction R1 indicated in FIG. 5A.

Furthermore, the semiconductor layer sequence can have a crystal axis tilt which increases in the region of a facet with decreasing distance to the facet in longitudinal direction 93, i.e. parallel to the direction R2 indicated in FIG. 5A. In particular, this can mean that the substrate has a first crystal axis K1 at the main surface 12, as indicated in FIG. 5B. The semiconductor layer sequence can have a second crystal axis K2, in particular on a side facing away from the substrate. Far from any recesses in the substrate, i.e., in a region of the substrate having a large distance, for example, a distance greater than or equal to 100 μm, from any recesses in the main surface of the substrate, the second crystal axis K2 can be, for example, parallel or substantially parallel to the first crystal axis K1. It can also be possible for the first and second crystal axes K1, K2 to include some angle other than 0 in such a region far from recesses in the main surface 12 of the substrate, but for this angle to be substantially constant over the far region. In the facet region, however, the angle between the first and second crystal axes K1, K2 can increase as the distance from the facet decreases in the longitudinal direction 93, as indicated in FIG. 5B.

Thus, as indicated in FIG. 5B, the closer one gets, following a lateral direction, to a recess in the main surface 15 of the substrate 1, the more a layer thickness, a composition and a tilting of the crystal axis can vary. For example, the decrease in thickness can be greater than or equal to 1% and less than or equal to 5% per 1 μm change in distance. The relative decrease in atomic concentration of a constituent of the material composition of a semiconductor layer such as the active layer can be, for example, greater than or equal to 5% and less than or equal to 15% per 1 μm change in distance. The increase in tilting of the second crystal axis K2, i.e., the crystal axis of the grown crystal, with respect to the first crystal axis K1, i.e., the crystal axis of the substrate, can be, for example, greater than or equal to 1º and less than or equal to 4° per 10 μm change in distance. Depending on the shape and position of the facets and the associated recesses, the effects described can vary in intensity. However, the lateral distance between facet-forming trenches and associated recesses in the main surface of the substrate is preferably always selected so that such an effect occurs in the region of the facets or at the facets.

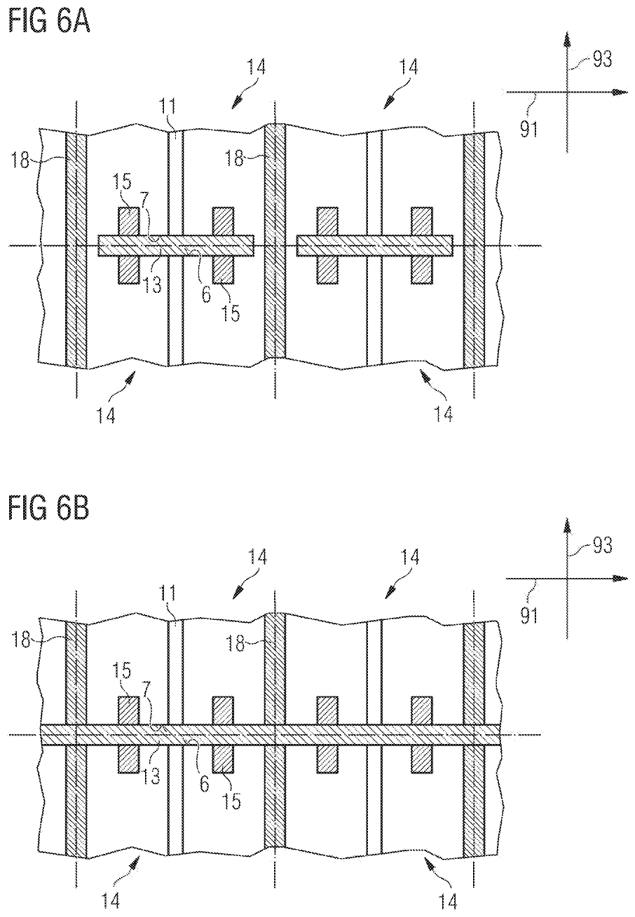

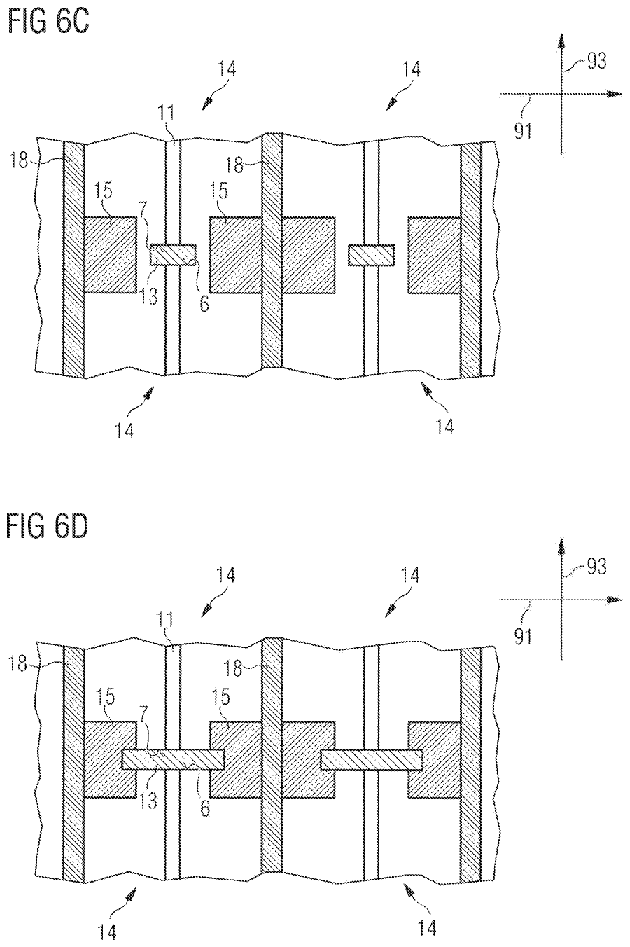

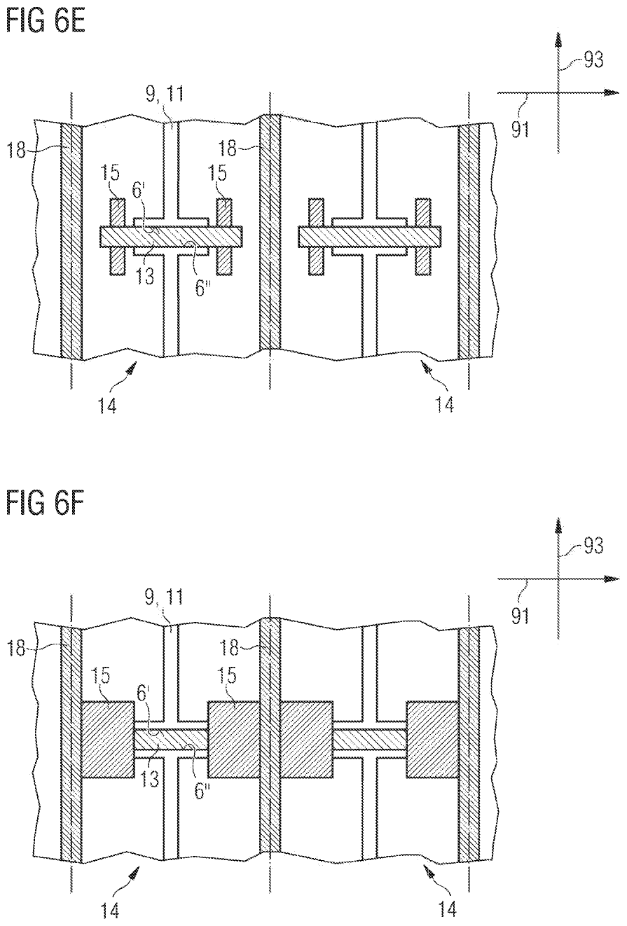

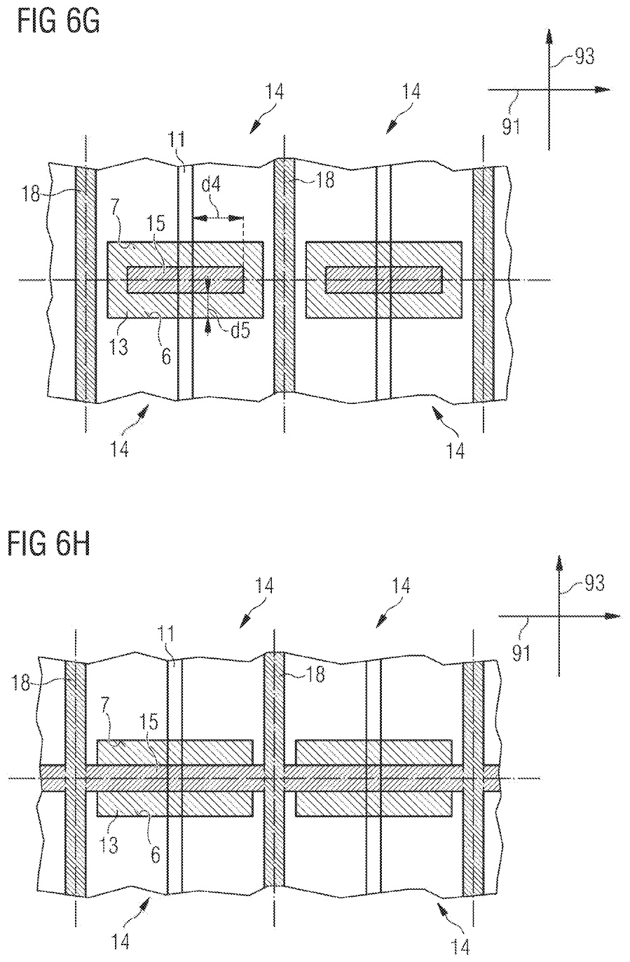

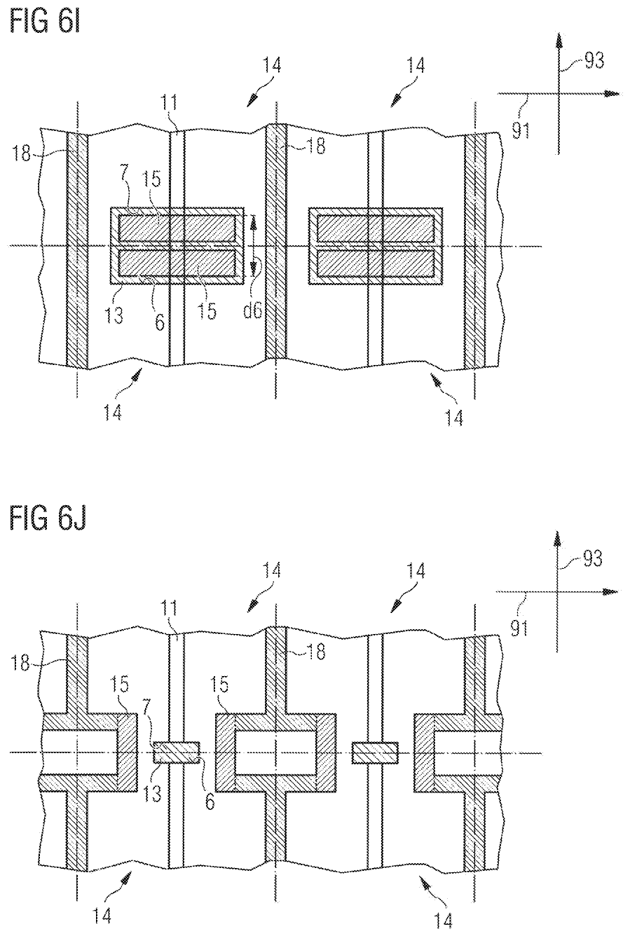

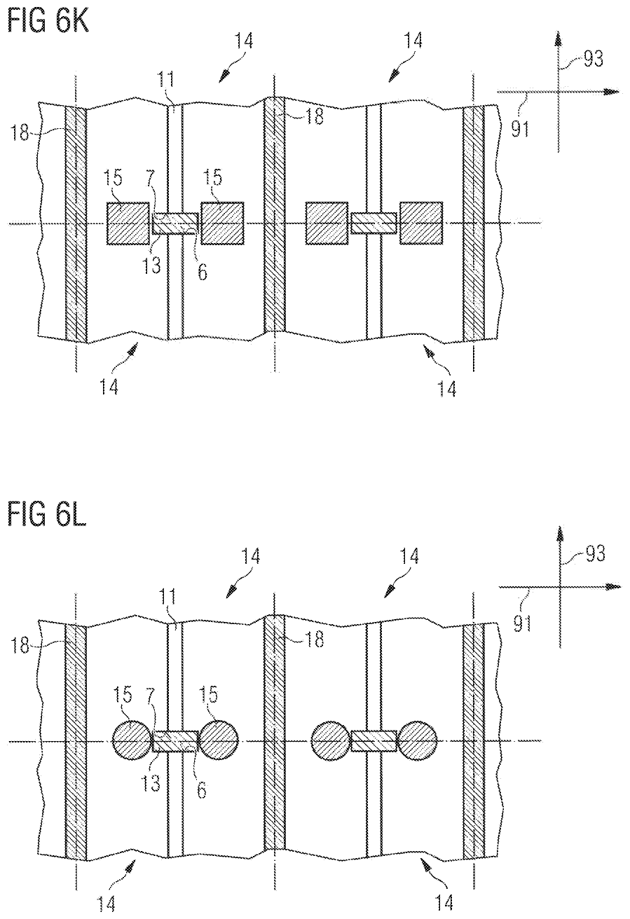

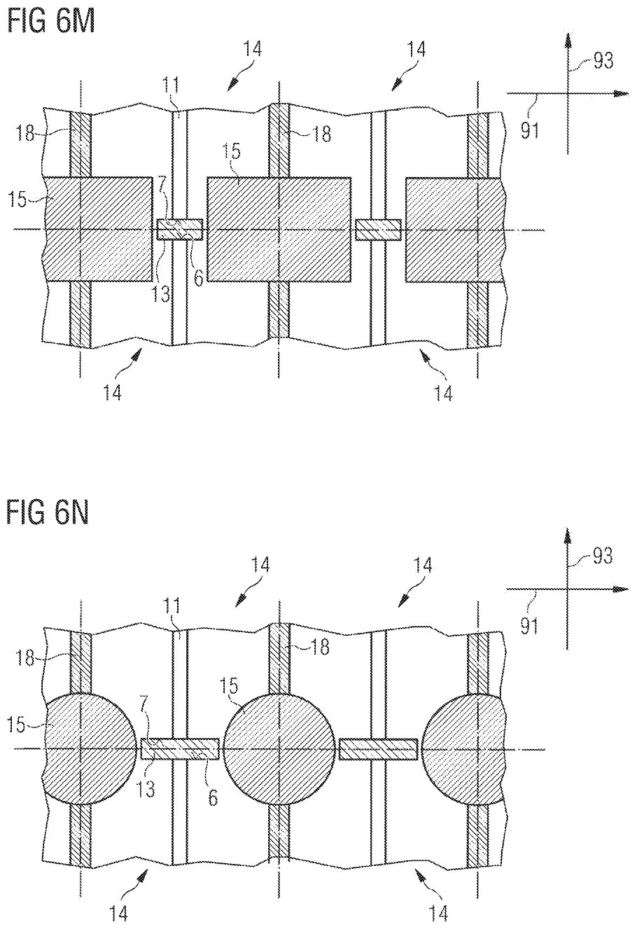

FIGS. 6A to 6N show further embodiments of particularly preferred arrangements and configurations of recesses 15 in the main surface of the substrate and of trenches 13 in the semiconductor layer sequence for forming facets, with facets 6, 7 again being indicated purely by way of example. However, the following embodiments apply equally to any facets formed in the semiconductor layer sequence.

As shown in the previous embodiments, the trenches 13 and thus the facets 6, 7 can have a distance greater than 0 in the lateral direction from the recesses 15. In other words, the trenches 13 and the recesses 15 do not overlap when viewed in the vertical direction.

FIG. 6A shows an embodiment in which a trench 13 is stretched in a transversal direction 91 over the associated recesses 15, thereby partially overlapping with the associated recesses 15.

As shown in FIG. 6B, a trench 13 can be formed to extend in the transversal direction 91 over multiple or all chip regions 14 arranged adjacent to each other in the transversal direction 91, so that a single trench 13 can be used to form facets in a plurality of chip regions 14.

As indicated in FIGS. 6C and 6D, the recesses 15 can also extend to the pre-patterning trenches 18 and thus be directly connected to the pre-patterning trenches 18 compared to the previous embodiments. In this case, as in the other embodiments, the recesses 15 and the pre-patterning trenches 18 with an equal depth or with different depths can be fabricated together or separately in the substrate, for example by etching processes. The trenches 13 and thus the facets 6, 7 in the semiconductor layer sequence can also in these cases be without overlap (FIG. 6C) or partially overlapping (FIG. 6D) with the recesses 15.

As described above, the trenches 13 can also be located in the region of semiconductor chips to be defined later and thus within the chip regions 14. For example, as indicated in FIGS. 6E and 6F, an element 11 defining the active region, such as a ridge waveguide structure 9, can be widened in the region of the facets. The widening does not have to be rectangular as indicated in FIGS. 6E and 6F, but can also have angles not equal to 90°, which can also be referred to as a so-called taper. Such an embodiment can have the advantage that during etching there is no step on the edge of the ridge waveguide structure which could interfere with the smoothing of the facets 6′, 6″.

With respect to their main direction of extension, the recesses 15 can also be perpendicular to the longitudinal direction 93 and thus along the transversal direction 91 and thus parallel to the trenches 13 and the facets 6, 7 defined by the trench production, as indicated in FIGS. 6G and 6H. Here, it can be possible for a trench 13 to be etched in the semiconductor layer sequence to completely enclose the at least one recess 15 in a top view along the vertical direction, as indicated in FIG. 6G. During the fabrication of the trenches 13 and thus of the facets 6, 7, the recesses 15 can also be completely removed. The advantage of this can be, for example, that the size ratios have only a minor influence and the region of the semiconductor layer sequence disturbed by the recesses can be at least partially or even completely removed. As shown in FIG. 6H, the recesses 15 can overlap with the pre-patterning trenches 18 and, as described further above, can be incorporated into the substrate, for example, in a common manufacturing step.

Even though the recesses 15 in the embodiments shown so far are formed as single recesses, the trenches 13 and thus the facets 6, 7 can also be associated with double or multiple recesses, as indicated in FIG. 6I. The distances d4, d5 and d6 drawn in FIGS. 6G and 6I can particularly preferably be small distances as defined above.

As shown in FIG. 6J, the recesses 15 can be formed as regions of the pre-patterning trenches 18, which can be, in the region of the facets, drawn to the to-be-defined facets 6, 7.

FIG. 6K shows another embodiment in which the recesses 15 are square. In addition to the rectangular cross-sections of the recesses 15 shown in the previous embodiments, the recesses 15 can also be at least partially round in shape. For example, the recesses 15 can have a circular cross-section in the main extension plane of the main surface of the substrate, as indicated in FIG. 6L. In addition, mixed forms of the cross-sectional shapes shown are also possible.

As indicated in FIGS. 6M and 6N, regardless of their shape, the recesses 15 can also be formed together with, or at least overlap with, the pre-patterning trenches 18.

The features and embodiments described in connection with the figures can also be combined with one another according to further embodiments, even if not all such combinations are explicitly described. Furthermore, the embodiments described in connection with the figures can alternatively or additionally have further features according to the description in the general part.

The invention is not limited by the description based on the embodiments to these embodiments. Rather, the invention includes each new feature and each combination of features, which includes in particular each combination of features in the patent claims, even if this feature or this combination itself is not explicitly explained in the patent claims or embodiments.

1.-16. (canceled)

17. A method for manufacturing a light-emitting semiconductor chip having a semiconductor layer sequence, wherein the semiconductor layer sequence has an active region, which extends in a longitudinal direction and which is configured for generating light with a radiation direction along the longitudinal direction, the method comprising:
providing a substrate having a main surface with at least one recess, the main surface having a main extension plane along the longitudinal direction and along a transversal direction perpendicular to the longitudinal direction, wherein the substrate has pre-patterning trenches formed along the transversal direction between chip regions and extending along the longitudinal direction;
growing the semiconductor layer sequence on the main surface with the at least one recess; and
forming at least one facet aligned along the transversal direction in the semiconductor layer sequence by an etching process, wherein the facet has a distance of less than or equal to 50 μm from the at least one recess in at least one direction parallel to the main extension plane of the main surface.

18. The method according to claim 17,
wherein the semiconductor layer sequence comprises a plurality of chip regions, each chip region corresponding to the light-emitting semiconductor chip,
wherein the at least one recess is associated with each chip region of the plurality of chip regions in the main surface,
wherein in each chip region of the plurality of chip regions, a facet aligned along the transversal direction is formed in the semiconductor layer sequence by an etching method,
wherein, for each chip region of the plurality of chip regions, the facet has a distance of less than or equal to 50 μm from the at least one associated recess in at least one direction parallel to the main extension plane of the main surface.

19. The method according to claim 17, wherein the facet has a distance of less than or equal to 50 μm from the at least one recess in the longitudinal direction and/or in the transversal direction.

20. The method according to claim 17, wherein an active region defining element is formed in the semiconductor layer sequence, and wherein the at least one recess has a distance of less than or equal to 50 μm in the transversal direction to the active region defining element.

21. The method according to claim 20, wherein the active region defining element is a ridge waveguide structure and/or a contact region of the semiconductor layer sequence with an electrode layer.

22. The method according to claim 17, wherein the facet, in a view along a vertical direction aligned perpendicular to the main extension plane, is formed at least partially above the recess.

23. The method according to claim 17, wherein a trench having a main extension direction in the transversal direction is formed to form the facet in the semiconductor layer sequence.

24. The method according to claim 17, wherein the substrate has at least two recesses in the main surface, and wherein the facet is formed symmetrically with respect to the at least two recesses.

25. The method according to claim 17, wherein at least one first facet is formed in the semiconductor layer sequence and at least one second facet is formed in the semiconductor layer sequence, and wherein each of the first and second facets has a distance of less than or equal to 50 μm from the at least one recess in at least one direction that is parallel to the main extension plane of the main surface.

26. The method according to claim 17, wherein the at least one recess has a depth of greater than or equal to 0.5 μm and less than or equal to 15 μm.

27. The method according to claim 17, wherein the at least one recess has an expansion in the longitudinal direction that is less than or equal to 30% of a cavity length.

28. The method according to claim 17, wherein the at least one recess has an expansion in the longitudinal direction of less than or equal to 100 μm.

29. The method according to claim 17, wherein the at least one recess in the main extension plane has a rectangular or circular cross-section.

30. A light emitting semiconductor chip comprising:
a semiconductor layer sequence comprising:
an active region extending in a longitudinal direction, the active region configured for generating light with a radiation direction along the longitudinal direction; and
a facet formed perpendicular to the longitudinal direction along a transversal direction and a vertical direction,
wherein at least one semiconductor layer of the semiconductor layer sequence in a region of the facet has a variation of one or more parameters selected from layer thickness, material composition or orientation of a crystal axis, and
wherein the active region comprises a material composition and a relative proportion of a component of the material composition in a region of the facet decreases in the longitudinal direction with decreasing distance from the facet and/or decreases at the facet in the transversal direction.

31. The semiconductor chip according to claim 30, wherein the at least one semiconductor layer of the semiconductor layer sequence in the region of the facet has a thickness, which decreases in the longitudinal direction as the distance from the facet decreases and/or wherein the active region at the facet has a thickness which decreases in the transversal direction.

32. The semiconductor chip according to claim 30,
wherein the semiconductor layer sequence is deposited on a substrate, the substrate having a first crystal axis at a main surface, and the semiconductor layer sequence having a second crystal axis, and
wherein an angle between the first and second crystal axes increases in an area of the facet with decreasing distance to the facet in the longitudinal direction.
